(19) United States
(12) Patent Application Publication
(10) Pub. No.: US 2010/0174957 A1
(43) Pub. Date: Jul. 8, 2010

(54) CORRELATION AND OVERLAY OF LARGE DESIGN PHYSICAL PARTITIONS AND EMBEDDED MACROS TO DETECT IN-LINE DEFECTS

(75) Inventors: Jonathan K. Winslow, II, Yorktown Heights, NY (US); Alisa Barth, Poughkeepsie, NY (US); Gary W. Maier, Poughquag, NY (US)

Correspondence Address: INTERNATIONAL BUSINESS MACHINES CORPORATION;DEPT. 18G, BLDG. 321-482, 2070 ROUTE 52, HOPEWELL JUNCTION, NY, 12533, US

(73) Assignee: International Business Machines Corporation, Armonk, NY (US)

(21) Appl. No.: 12/350,261

(22) Filed: Jan. 8, 2009

(51) Int. Cl. G01R 31/3177; G06F 11/25

(52) U.S. Cl. 714/727; 714/E11.155

(57) ABSTRACT

A method of identifying defects in a chip integral to a wafer by correlating physical defects to a corresponding logic fail. The method includes partitioning a logic representation of the chip; identifying physical defects and determining corresponding coordinates of each identified physical defect; determining boundaries of the failing logic partitions, each logic partition being bound by coordinates; and correlating the physical coordinates of the defects to the bounded failing logic partitions. The scaled back, low overhead method correlates design sensitivities and test fails to physical process defects detected during semiconductor manufacturing in-line test inspection. It further identifies and records design physical coordinates of large embedded logic physical partitions test structures, memory arrays, and the like.

### FIELD OF THE INVENTION

The invention generally relates to the field of automating the design of integrated circuit chips (ICs), and more particularly, to a system and a method for improving the yield of the ICs to detect the presence of in-line defects.

### BACKGROUND OF THE INVENTION

Semiconductor manufacturing is known in industry to be a highly complex process. With ever increasing circuit densities, the task of verifying a design and testing the functionality of a chip has become increasingly more difficult. The number of steps involved as well as features measured in nanometers makes the process highly susceptible to defects and failures. Mature technologies often measure their yields in the 50-75% range and early technologies often measure them in single digits, depending on the chip size and complexity.

In order to maximize yield learning, characterization engineers are tasked to detect defects through electrical and physical signals, quantifying yield impact and prioritizing the defects so that the manufacturing engineers can channel their efforts towards reducing those defects that have the highest impact on the yield.

A major problem that currently exists is that there are many different sources of information pertaining to defects, all of which have significant benefits and significant drawbacks. Using any one solution provides only part of the answer, and using several of the techniques often provides conflicting answers. It is only when a methodology is provided that integrates these signals that one begins to turn the data into actionable information.

Advanced diagnostic techniques have been developed for integrating multiple data sources together with creating a sophisticated and valuable output to direct the manufacturing community towards those defects that will utilize their efforts most efficiently and show the greatest return on investment in terms of yield. These advanced techniques often require detailed design information so that different pieces of data can be merged. When a chip design is internally generated, obtaining detailed design information can be accomplished with little difficulty. Unfortunately, many products such as microprocessors are manufactured by silicon foundries that imply that the entity designing the chip is not the one that manufactures the final product.

Moreover, since microprocessors provide a customer with a competitive advantage, the design information is kept as a proprietary asset, and is not shared with the manufacturer of the product. Accordingly, advanced diagnostic techniques are not available and innovative solutions become a necessity to somehow compensate for the lack of availability of this information. As a rule, particularly when dealing with foundry customers, information such as a net list, annotated physical design, diagnostic test patterns are not available, as they are considered proprietary.

For illustrative purposes, FIG. 1 shows a schematic diagram of a prior art microprocessor. Practitioners of the art will ready recognize that the microprocessor is intended to be complemented with logic forming part of the microprocessor chip, the combination of which is treated as proprietary information. Generally, it is known in the art that a chip consists of a mixture of combinatorial and sequential logic, the details of which are not pertinent to the present invention, and will not, therefore, be further discussed.

Still referring to FIG. 1, the aforementioned microprocessor is shown subdivided in a plurality of partitions, identified by an arbitrary nomenclature, e.g., FC, SU, SH and the like. In the case of a Level Sensitive Scan Design (LSSD), each partition may include, in addition, a number of scan chains.

Photo inspection is one of the common techniques for detecting the presence of photo defects found during the semiconductor manufacturing process. Level scans are performed on the wafer surface to detect these and other defects and anomalies. This information is fed back to the manufacturer to highlight the defect pareto, making it possible to work on the most common defects first, followed by improving yield at the most efficient rate. A big challenge remains that is associated with photo inspection to detect anything the tool determines to be anomalous. Some of these result in failures (referred to killer defects), while others do not (referred to nuisance defects). Differentiating between nuisance defects and killer defects is an entire area of specialization, and can be done fairly well on a large sample statistical basis, but it is nearly impossible to duplicate this on a case by case basis.

Typically, a design database containing net lists and annotated physical design are provided to perform a PLY (process limited yield) defect to design the shape overlay. Volume electrical diagnostic data, such as bitmaps, logic net calls, and the like, is collected during wafer final test using diagnostic patterns, and diagnostics simulations are performed on the gathered data, followed by logical nets to physical shapes conversion to obtain coordinates of the failing circuits. More particularly, proprietary information includes failing latches or logic gates. Similarly, information leading to failing array cells may, likewise, be associated to their respective defect locations, both of which can be shown in the form of detailed high volume bitmaps, all of which greatly simplify the process of determining the exact location of the defects, albeit the expense associated with costly engineering overhead, added manufacturing test cost and diagnostic data collection.

Generally, array cell level data among others, is provided usually in the form of netlists requiring design libraries and connectivity information, requiring the use of proprietary information. Consequently, logic diagnostic tools are customized to specifically handle confidential data.

In view of the lack of non-proprietary design data, particularly regarding the logic representation of the chip that is not shared with the manufacturing company, there exists a need for advanced low cost and low engineering overhead diagnostic techniques that are presently unavailable, and for new and innovative solutions to circumvent the aforementioned problems.

### SUMMARY OF EMBODIMENTS OF THE INVENTION

Accordingly, it is an object of the present invention to correlate physical defects to a macro or partition of a chip design in the absence of a logic description thereof.

It is another object to identify and test failing chips or macros, or physical portions thereof by structuring manufacturing test flow and generating test patterns that provide pass/fail data, bin and sort information of the failing large portions of embedded logic, test, array, and core sub-partitions of the chip design.

It is still another object to correlate physical defects found in a chip to their electrical failures by determining their location initially to the partition, by first framing the failure within predetermined bounds, followed by mapping the precise location of the defect through exact coordinates.

According to one aspect of the present invention, failing partitions are determined by correlating the wafer final test logic failing scan chains with the logical partitions they are embedded in, and the coordinate system associated with each logical partition.

Furthermore, a system and a method are provided for overlaying photo defect x,y coordinates with the coordinate boundaries of the failing partition. This methodology provides a highly reliable way to correlate photo defects with the resulting logical fails while avoiding the need for annotated physical layout information (GL1) and detailed design information which foundry customers often treat as proprietary.

According to another aspect of the present invention, a method and a system are provided that correlate chip logical partitions to a corresponding physical representation that does not require design proprietary data.

The method relies on non-proprietary manufacturing information associated with the partitions forming the chip. It enables the use of PLY to WFT failure overlay without requiring detailed design information which foundry customers are unwilling to share.

According to still another aspect of the present invention, a method is provided for identifying defects in a chip integral to a wafer by correlating physical defects to a corresponding logic fail, the method including: a) partitioning a logic representation of the chip into a plurality of partitions; b) identifying physical defects, and determining corresponding coordinates of each identified physical defect; c) determining boundaries of the failing logic partition, each logic partition being bound by coordinates; and d) correlating the physical coordinates of the defect to the bounded failing logic partition.

In yet another aspect of the invention, both the physical representation of the chip in the form of a layout and the logical representation formed by logic and scan chains restricted to non-proprietary manufacturing data, wherein the logic representation includes failing logic partitioning and defect locations; logic maps for deriving failing latches or gates; and failing array partitions and defect locations.

### BRIEF DESCRIPTION OF THE DRAWINGS

The above and other objects, features and advantages of the present invention will become more fully understood from the detailed description given hereinafter and the accompanying drawings, which are given by way of illustration only and thus are not to be considered as limiting the present invention.

FIG. 1 shows a schematic diagram of a conventional prior art microprocessor chip partitioned into a series of logic partitions.

FIG. 2 shows a graphical representation of a sequence of steps leading to localizing a defect within a failing chip according to an embodiment of the invention;

FIG. 3 is a flowchart illustrating the steps for overlaying in-line photo inspection defects with the electrical failing partition, according to an embodiment of the present invention; and

FIG. 4 shows logic to partition correlation table that translates Wafer Final Test (WFT) data into partitions with boundary coordinates, according to an embodiment of the invention.

### DETAILED DESCRIPTION OF PREFERRED EMBODIMENTS

The present invention and various features, aspects and advantageous details thereof are explained more fully with reference to non-limiting embodiments that are illustrated in the accompanying drawings and detailed in the following description.

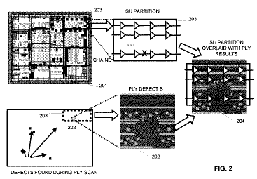

Referring to FIG. 2, there is shown photo inspection defect information overlaying a partition indicating the presence of a logic fail resulting from WFT. If the defect observed—preferably by way of photo inspection falls within the confines of the partition that was found to fail at WFT—, then it can be determined with a high degree of confidence that the defect observed is the cause of the logical fail detected at WFT.

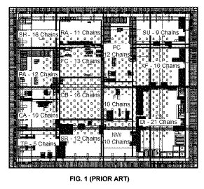

FIG. 2 further shows a graphical representation of a sequence of steps leading to localizing a defect in a failing chip, according to an embodiment of the invention. For demonstrative purposes only, the prior art microprocessor shown in FIG. 1 will be used to illustrate aspects of the present invention.

Referring to block (201), when a tool detects the presence of a defect, it collects and records pertinent information such as Wafer ID, coordinates, level, and size information. Subsequently, a sample of the defects detected are reviewed and analyzed in the SEM, and analyzed to determine the type of defect that was observed by the tool.

Referring to block (202), once the wafer the manufacturing process has been completed, it is sent onto Wafer Final Test (WFT), where each product chip is probed and tested for functionality. Current semiconductor test methodology involves preconditioning the chip with logic patterns, applying clock pulses and validating the resulting values of those patterns. Preconditioning and validating those patterns are performed through scan chains that are embedded in the chip, and which are vital components that enable testing the chip. When there is a defect is located in the scan chain, it is usually detected during the scan chain integrity test. Furthermore, when a logical fail within the design is encountered, it is detected during the reading of the output of the scan chains during a scan out operation.

As part of hierarchical chip design, microprocessors are often subdivided into logical partitions whose design and layout are generated independently of one another, and subsequently merged together at the tail end of the design phase. The various partitions have multiple scan chains and SRAMs embedded therein and restricted to the logical (and physical) partition, as depicted in the prior art FIG. 1 showing the microprocessor formed by a plurality of logical partitions along with their respective physical boundaries, referred by numeral 201, FIG. 2. When a logic, chain or SRAM fail occurs and is detected during the wafer final test, the location of the physical defect causing the logic or the chain to fail can be bounded by the partition containing the defect.

Assuming that a scan operation has been completed showing the presence of a plurality of defects in the chip (203), one of which is positioned in the upper right corner of the first quadrant (204). The defect is inspected, preferably using a scanning electron microscope (SEM).

Assuming that partition SU (202) of microprocessor (201) contains a defect in chain D, i.e., in one of the nine chains in the partition SU. Shown in (205) is a physical representation of the SU partition, indicative of a failure caused by an open circuit.

SU partition (202) is then overlaid over the physical representation of SU (205) containing the aforementioned defect, the combined drawing being illustrated in block (206). Upon examining the combined picture, one may then determine that the defect impacts chain D, severing the connection between two gates forming the chain.

In this manner, coupling the physical representation of a partition to its corresponding logic representation creates a combination devoid of any proprietary information.

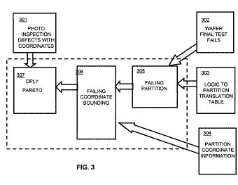

Referring now to FIG. 3, there is shown a flow chart illustrating how the logic representation of the SRAM and scan chains thereof correlates to the corresponding physical partitions.

Using translation table (305) to achieve this correlation, fail data from WFT (302) can be bucketed into the appropriate failing partition (305). The logic-to-partition translation table (303) makes it possible to identify the appropriate failing partition (305).

Based on the partition coordinate information (304), the failing partition (305) is now converted into a physically bounded region (306) where the actual logical fail occurs, the logic fail being identified by its corresponding coordinates.

Referring now to the physical portion of the failing partition, defects are identified preferably by way of photo inspection and subsequently recorded, utilizing for this purpose the respective coordinates (301). The defect pareto (307) provides a defects library, consisting of the defects identified at WFT. Using the appropriate set of coordinates, the corresponding defects are paired with the corresponding failing partition, which is itself recognized by the failing coordinate bounding (206).

Once this design to defect (e.g., PLY) overlay is completed, product based defect Limited Yields (LYs) are determined for all the defects that were correlated to their respective failing partitions.

Weighting the observed defects is known in industry to be a difficult problem that industry has struggled with. The present methodology makes it possible to come up with an accurate and reliable method for prioritizing defects for the process community. The final product, shown below, provides weighted pareto of (DPLY) defects that can be used by manufacturing engineering.

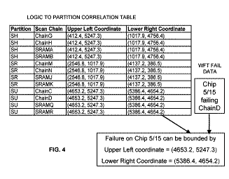

Referring now to FIG. 4, there is shown a logic-to-partition correlation table that translates WFT data into bounded coordinates, according to an embodiment of the invention.

For illustrative purposes, the correlation table is shown only listing partitions forming the illustrative microprocessor (col. 1), followed by the corresponding ID of the scan chain (col. 2). Following, on columns 3 and 4, an upper (left) and lower (right) coordinates are depicted that provide an upper and lower bound of the defect. Thus, the failing chip is identified first as occurring on the chip with wafer position 5/15 (X=5, Y=15), and more specifically, in chain D, partition SU.

Subsequently, upper and lower bounds are preferably further refined to actual coordinates. In the present illustration, the coordinates for the upper bounds are (4653.2, 5247.3), and for the lower bounds (5386.4, 4654.2).

Upon overlaying the logic representation superimposed over the physical partition, the defect is seen matching the logic defect detected by WFT to the actual physical defect preferably identified by an SEM picture.

Although illustrative embodiments of the present invention have been described herein with reference to the accompanying drawings, it is to be understood that the invention is not limited to the precise embodiments, and that various other changes and modifications may be made by one skilled in the art without departing from the scope or spirit of the invention.

What is claimed is:

1. A method of identifying defects in a chip integral to a wafer by correlating physical defects to a corresponding logic fail, the method comprising:
a) partitioning a logic representation of the chip into a plurality of partitions;
b) identifying physical defects and determining corresponding coordinates of each identified physical defect;
c) determining boundaries of the failing logic partitions, each logic partition being bound by coordinates; and
d) correlating the physical coordinates of the defects to the bounded failing logic partitions.

2. The method according to claim 1 wherein said defects are photo inspection defects.

3. The method according to claim 1 wherein said physical defects are identified by scanning the wafer.

4. The method according to claim 1 wherein each partition is provided with at least one scan chain.

5. The method according to claim 4, wherein the failing partitions are determined by correlating electrical test logic fails determined by scan chains with the logical partitions they are embedded therein.

6. The method according to claim 1 further comprising bounding each identified fail through at least first and second coordinates.

7. The method according to claim 6 wherein said at least first and second coordinates comprise an upper coordinate and a lower coordinate.

8. The method according to claim 7, wherein a match is generated upon detecting a physical defect falling within the upper coordinate and the lower coordinate.

9. The method according to claim 1, further comprising recording the physical coordinates of the electrical fails, said fails being identified from a selected group consisting of embedded logic physical partitions test structures, memory arrays, and scanning chains and any combination thereof.

10. The method according to claim 1, wherein said physical representation is a layout.

11. The method according to claim 1, further comprising correlating physical defects to a macro or partition of a chip design in absence of its logic description. thereof.

12. The method according to claim 1, wherein test failing chips or macros or physical portions thereof are identified by structuring manufacturing test flow and generating test patterns that provide pass and fail data, bin and sort data of portions of embedded logic, test, array, and core sub-partitions of the chip design.

13. A method of identifying defects in a chip integral to a wafer by correlating physical defects to a corresponding logic fail, the method comprising:
a) partitioning a logic representation of the chip;
b) determining for each identified physical defect its corresponding x and y coordinates;
c) determining boundaries of each failing logic partition, each logic partition being bound by upper and lower coordinates; and
d) correlating each identified physical defect to its corresponding bounded failing logic partition.

14. The method according to claim 13, wherein said physical defects are detected by in-line testing.

15. The method according to claim 13, wherein in step d), said correlating is performed by overlaying the physical defect to its corresponding bounded failing logic partition.

16. The method according to claim 13, wherein in step d) said correlating is performed by matching the logic defect detected by wafer final test (WFT) to the physical defect.

17. The method according to claim 16, wherein said physical defect is identified by a scanning electron microscope (SEM) picture.
